(19) United States
(12) Patent Application Publication
(10) Pub. No.: US 2024/0291227 A1
(43) Pub. Date: Aug. 29, 2024

(54) METHOD FOR MANUFACTURING SEMICONDUCTOR LASER DEVICE

(71) Applicant: HAMAMATSU PHOTONICS K.K., Shizuoka (JP)

(72) Inventors: Satoru OKAWARA, Shizuoka (JP); Atsushi Sugiyama, Shizuoka (JP); Takehito Nagakura, Shizuoka (JP); Keita Furuoka, Shizuoka (JP)

(73) Assignee: HAMAMATSU PHOTONICS K.K., Shizuoka (JP)

(21) Appl. No.: 18/584,232

(22) Filed: Feb. 22, 2024

(30) Foreign Application Priority Data
Feb. 28, 2023 (JP) 2023-030073

(51) Int. Cl. H01S 5/02; H01S 5/0238; H01S 5/32

(52) U.S. Cl. CPC H01S 5/0202; H01S 5/0206; H01S 5/0238; H01S 5/3202

(57) ABSTRACT

Provided is a method for manufacturing a semiconductor laser device that includes a semiconductor substrate, and a semiconductor stacked body including an active layer and formed on the semiconductor substrate. The method includes a first step of preparing a wafer including a plurality of device portions to each become the semiconductor laser device, the plurality of device portions being arranged in a first direction perpendicular to an optical waveguide direction of the semiconductor stacked body, and a second step of forming a pressing mark group including a plurality of continuous pressing marks on a first primary surface of the wafer or a second primary surface opposite to the first primary surface to be positioned on each of a plurality of first boundary lines that partition the plurality of device portions arranged in the first direction after the first step.

### TECHNICAL FIELD

The present disclosure relates to a method for manufacturing a semiconductor laser device.

### BACKGROUND

A method for dividing a wafer into a plurality of laser bars by primary cleavage (primary scribing and primary breaking) and then dividing each laser bar into a plurality of semiconductor laser devices by secondary cleavage (secondary scribing and secondary breaking) has been known as a method for manufacturing a semiconductor laser device (for example, Japanese Unexamined Patent Publication No. 2003-17791). In such a method for manufacturing a semiconductor laser device, there is a case where a scribe for dividing each laser bar into a plurality of semiconductor laser devices is put by a diamond tool as secondary scribing for each laser bar.

### SUMMARY

In the method for manufacturing a semiconductor laser device as described above, when the diamond tool is not precisely controlled in the secondary scribing for each laser bar, a lateral crack (crack generated in a direction parallel to the primary surface of the laser bar corresponding to the primary surface of the wafer from immediately below a pressing mark) may occur along a scribe, and thus, there is a concern that the lateral crack remains in the obtained semiconductor laser device. Since the lateral crack remaining in the semiconductor laser device causes large-scale brittle fracture, peeling, chipping, and the like in the semiconductor laser device are caused.

An object of the present disclosure is to provide a method for manufacturing a semiconductor laser device capable of suppressing remaining of a lateral crack in an obtained semiconductor laser device.

A method for manufacturing a semiconductor laser device according to an aspect of the present disclosure is a method for manufacturing a semiconductor laser device that includes a semiconductor substrate, and a semiconductor stacked body including an active layer and formed on the semiconductor substrate. The method includes a first step of preparing a wafer including a plurality of device portions to each become the semiconductor laser device, the plurality of device portions being arranged in a first direction perpendicular to an optical waveguide direction of the semiconductor stacked body, and a second step of forming a pressing mark group including a plurality of continuous pressing marks on a first primary surface of the wafer or a second primary surface opposite to the first primary surface to be positioned on each of a plurality of first boundary lines that partition the plurality of device portions arranged in the first direction after the first step.

### BRIEF DESCRIPTION OF THE DRAWINGS

FIG. 1 is a plan view of a semiconductor laser device manufactured by a method for manufacturing a semiconductor laser device according to an embodiment;

FIG. 2 is a cross-sectional view of the semiconductor laser device taken along line II-II illustrated in FIG. 1;

FIG. 3 is a plan view of a wafer for explaining a first step of the method for manufacturing a semiconductor laser device according to the embodiment;

FIG. 4 is a cross-sectional view illustrating a portion of the wafer illustrated in FIG. 3;

FIGS. 5A and 5B are a plan view of the wafer for explaining a second step of the method for manufacturing a semiconductor laser device according to the embodiment, and a plan view of the wafer for explaining a third step of the method for manufacturing a semiconductor laser device according to the embodiment;

FIGS. 6A and 6B are a plan view of a laser bar for explaining a fourth step of the method for manufacturing a semiconductor laser device according to the embodiment, and a plan view of a plurality of semiconductor laser devices for explaining a fifth step of the method for manufacturing a semiconductor laser device according to the embodiment;

FIG. 7 is a plan view of a pressing mark group formed in the method for manufacturing a semiconductor laser device according to the embodiment;

FIG. 8 is a plan view of a part of the wafer on which the pressing mark group illustrated in FIG. 7 is formed;

FIGS. 9A and 9B are side views of a gear-shaped wheel used for forming the pressing mark group illustrated in FIG. 7;

FIGS. 10A and 10B are diagrams illustrating a photograph of a part of a side surface of a semiconductor laser device obtained by a method for manufacturing a semiconductor laser device according to a comparative example and a photograph of a part of a side surface of a semiconductor laser device obtained by a method for manufacturing a semiconductor laser device according to an example;

FIG. 11 is a plan view of a part of a wafer for explaining a second step of a method for manufacturing a semiconductor laser device according to a modification;

FIG. 12 is a plan view of a part of a wafer for explaining a second step of the method for manufacturing a semiconductor laser device according to the modification; and

FIGS. 13A and 13B are plan views of a part of the wafer for explaining the second step of the method for manufacturing a semiconductor laser device according to the modification.

### DETAILED DESCRIPTION

Hereinafter, embodiments of the present disclosure will be described in detail with reference to the drawings. Note that, the same or corresponding parts in the respective drawings are denoted with the same reference signs, and repetitive descriptions will be omitted.

### [Configuration of Semiconductor Laser Device]

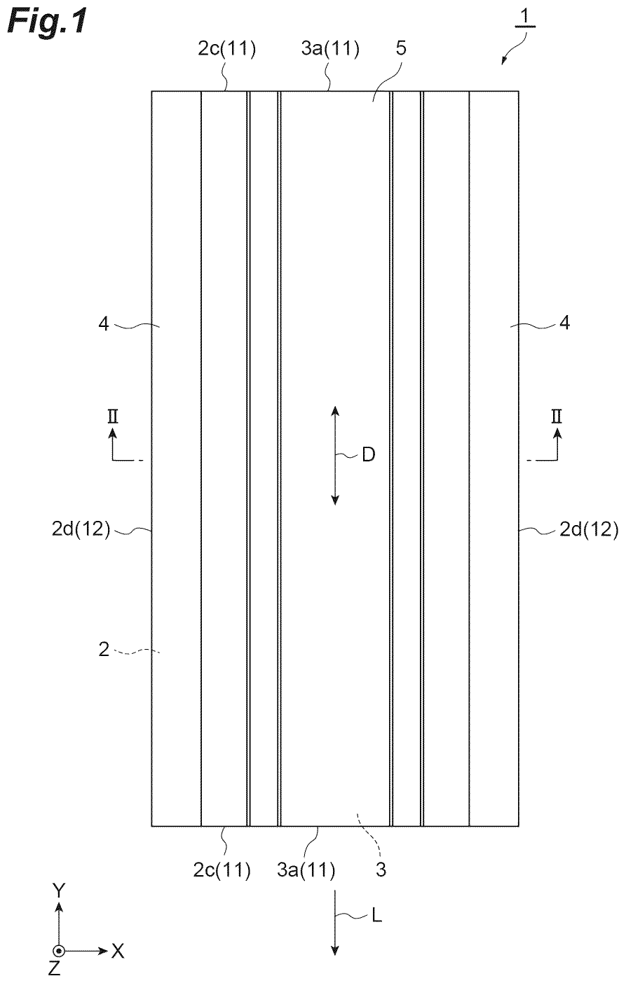

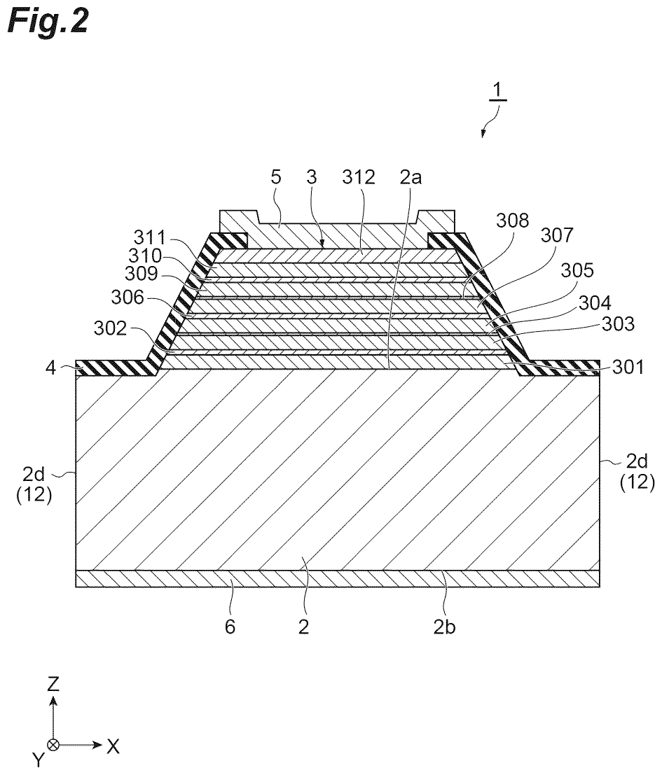

As illustrated in FIGS. 1 and 2, a semiconductor laser device 1 includes a semiconductor substrate 2 and a semiconductor stacked body 3. The semiconductor stacked body 3 has a pair of end surfaces 3a facing each other in an optical waveguide direction D. The semiconductor laser device 1 causes a laser beam L to resonate between the pair of end surfaces 3a, and emits the laser beam L from one end surface 3a along the optical waveguide direction D. That is, the semiconductor laser device 1 is formed as an end surface emission type laser diode. Hereinafter, a thickness direction of the semiconductor substrate 2 is referred to as a Z-axis direction, a first direction perpendicular to the optical waveguide direction D as viewed from the thickness direction of the semiconductor substrate 2 is referred to as an X-axis direction, and a second direction parallel to the optical waveguide direction D as viewed from the thickness direction of the semiconductor substrate 2 is referred to as a Y-axis direction. Note that, the first direction may be a direction in which the pair of end surfaces intersecting the optical waveguide direction face each other. In addition, the first direction may be a direction along an emission end surface of the laser beam.

The semiconductor substrate 2 is a GaAs single crystal substrate. The semiconductor substrate 2 has a front surface 2a and a back surface 2b facing each other in the Z-axis direction, a pair of side surfaces 2c facing each other in the Y-axis direction, and a pair of side surfaces 2d facing each other in the X-axis direction. In the semiconductor substrate 2, the Z-axis direction is a [100] direction, the Y-axis direction is a [01-1] direction, and the X-axis direction is a [0-1-1] direction. A shape of the semiconductor substrate 2 as viewed from the Z-axis direction is, for example, a rectangular shape with the Y-axis direction as a long side direction. As an example, a thickness of the semiconductor substrate 2 in the Z-axis direction is 100 to 200 μm, a width of the semiconductor substrate 2 in the X-axis direction is 300 to 600 μm, and a length of the semiconductor substrate 2 in the Y-axis direction is 600 to 1000 μm.

The semiconductor stacked body 3 is formed on the front surface 2a of the semiconductor substrate 2. That is, the semiconductor stacked body 3 is formed on the semiconductor substrate 2. A width of the semiconductor stacked body 3 in the X-axis direction is smaller than the width of the semiconductor substrate 2 in the X-axis direction. That is, the semiconductor stacked body 3 is formed in a mesa shape. In the semiconductor stacked body 3, a pair of side surfaces facing each other in the X-axis direction are inclined to approach each other with increasing distance from the semiconductor substrate 2. One end surface 3a of the semiconductor stacked body 3 is positioned on the same plane as one side surface 2c of the semiconductor substrate 2. The other end surface 3a of the semiconductor stacked body 3 is positioned on the same plane as the other side surface 2c of the semiconductor substrate 2. As an example, a thickness of the semiconductor stacked body 3 in the Z-axis direction is 10 to 15 μm, the width (maximum width) of the semiconductor stacked body 3 in the X-axis direction is 100 to 300 μm, and a length of the semiconductor stacked body 3 in the Y-axis direction is 600 to 1000 μm.

An insulating film 4 is formed on a region of the front surface 2a of the semiconductor substrate 2 where the semiconductor stacked body 3 is not formed and on the pair of side surfaces of the semiconductor stacked body 3. The insulating film 4 is, for example, a SiN film or a SiO₂ film. A first electrode 5 is formed on a front surface of the semiconductor stacked body 3 opposite to the semiconductor substrate 2. The first electrode 5 is electrically connected to the semiconductor stacked body 3. The second electrode 6 is formed on the back surface 2b of the semiconductor substrate 2. The second electrode 6 is electrically connected to the semiconductor substrate 2.

As an example, the semiconductor stacked body 3 is formed by stacking a lower first cladding layer 301, a lower active layer (active layer) 302, a lower second cladding layer 303, a lower tunnel barrier layer 304, an intermediate first cladding layer 305, an intermediate active layer (active layer) 306, an intermediate second cladding layer 307, an intermediate tunnel barrier layer 308, an upper first cladding layer 309, an upper active layer (active layer) 310, an upper second cladding layer 311, and a contact layer 312 in this order on the front surface 2a of the semiconductor substrate 2. The semiconductor stacked body 3 can be formed by growing these layers on the front surface 2a of the semiconductor substrate 2 by using, for example, a metalorganic chemical vapor deposition (MOCVD) method.

In this example, a first laser diode including the upper first cladding layer 309, the upper active layer 310, and the upper second cladding layer 311, a second laser diode including the intermediate first cladding layer 305, the intermediate active layer 306, and the intermediate second cladding layer 307, and a third laser diode including the lower first cladding layer 301, the lower active layer 302, and the lower second cladding layer 303 are connected in series. In the semiconductor laser device 1, a forward current flows from the first electrode 5 on a P-type semiconductor side to the second electrode 6 on an N-type semiconductor side, and thus, each of the first laser diode, the second laser diode, and the third laser diode emits light, and the laser beam L is emitted from the one end surface 3a along the optical waveguide direction D.

Examples of a combination of a thickness of each layer constituting the semiconductor stacked body 3, a suitable range of the thickness, and a conductivity type is shown in Table 1. Examples of a combination of a material and an impurity concentration of each layer constituting the semiconductor stacked body 3 is shown in Table 2. The number of active layers stacked in the semiconductor stacked body 3 is not limited to three and may be four or more.

TABLE 1

| | Thickness | Suitable range of | Conductive |
|---|---|---|---|
| Device | (μm) | thickness (μm) | type |
| Contact layer 312 | 0.2 | 0.05 or more and | P |
| | | 2.0 or less | |
| Upper second cladding | 2.0 | 1.5 or more and | P |
| layer 311 | | 3.0 or less | |
| Upper active layer 310 | 0.02 | 0.01 or more and | |
| | | 0.1 or less | |
| Upper first cladding | 2.0 | 1.5 or more and | N |
| layer 309 | | 3.0 or less | |
| Intermediate tunnel | 0.2 | 0.05 or more and | |
| barrier layer 308 | | 0.4 or less | |
| Intermediate second | 2.0 | 1.5 or more and | P |
| cladding layer 307 | | 3.0 or less | |
| Intermediate active layer | 0.02 | 0.01 or more and | |
| 306 | | 0.1 or less | |
| Intermediate first | 2.0 | 1.5 or more and | N |
| cladding layer 305 | | 3.0 or less | |
| Lower tunnel barrier | 0.2 | 0.05 or more and | |
| layer 304 | | 0.4 or less | |
| Lower second cladding | 2.0 | 1.5 or more and | P |
| layer 303 | | 3.0 or less | |
| Lower active layer 302 | 0.02 | 0.01 or more and | |
| | | 0.1 or less | |
| Lower first cladding | 2.0 | 1.5 or more and | N |
| layer 301 | | 3.0 or less | |
| Semiconductor substrate | 120 | 90 or more and | N |
| 2 | | 150 or less | |

TABLE 2

| | | | Suitable range |
|---|---|---|---|
| | | Impurity | of impurity |
| | | concentration | concentration |
| Device | Material | (cm⁻³) | (cm⁻³) |
| Contact layer 312 | GaAs | 1 × 10²⁰ | 1 × 10¹⁹ or more |
| | | | 2 × 10²⁰ or less |
| Upper second cladding | AlGaAs | 1 × 10¹⁸ | 1 × 10¹⁷ or more |
| layer 311 | | | 2 × 10¹⁸ or less |
| Upper active layer 310 | InAlGaAs | Non-doped | — |
| Upper first cladding | AlGaAs | 1 × 10¹⁸ | 1 × 10¹⁷ or more |
| layer 309 | | | 2 × 10¹⁸ or less |
| Intermediate tunnel | GaAs | 1 × 10¹⁹ | 5 × 10¹⁸ or more |
| barrier layer 308 | | | 1 × 10²⁰ or less |
| Intermediate second | AlGaAs | 1 × 10¹⁸ | 1 × 10¹⁷ or more |
| cladding layer 307 | | | 2 × 10¹⁸ or less |
| Intermediate active | InAlGaAs | Non-doped | — |
| layer 306 | | | |
| Intermediate first | AlGaAs | 1 × 10¹⁸ | 1 × 10¹⁷ or more |
| cladding layer 305 | | | 2 × 10¹⁸ or less |
| Lower tunnel barrier | GaAs | 1 × 10¹⁹ | 5 × 10¹⁸ or more |
| layer 304 | | | 1 × 10²⁰ or less |
| Lower second cladding | AlGaAs | 1 × 10¹⁸ | 1 × 10¹⁷ or more |
| layer 303 | | | 2 × 10¹⁸ or less |
| Lower active layer 302 | InAlGaAs | Non-doped | — |
| Lower first cladding | AlGaAs | 1 × 10¹⁸ | 1 × 10¹⁷ or more |
| layer 301 | | | 2 × 10¹⁸ or less |
| Semiconductor | GaAs | 1 × 10¹⁸ | 5 × 10¹⁷ or more |
| substrate 2 | | | 2 × 10¹⁸ or less |

### [Method for Manufacturing Semiconductor Laser Device]

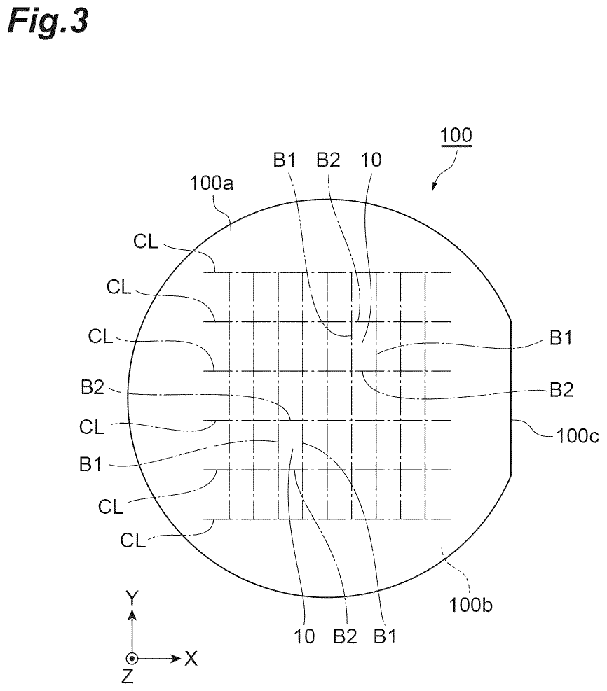

First, as illustrated in FIG. 3, a wafer 100 is prepared (first step). The wafer 100 has a first primary surface 100a and a second primary surface 100b opposite to the first primary surface 100a. The wafer 100 includes a plurality of device portions 10 to each become the semiconductor laser device 1. The plurality of device portions 10 are arranged in a matrix in the X-axis direction and the Y-axis direction. In a case where a thickness direction of the wafer 100 is the Z-axis direction, the X-axis direction is a direction perpendicular to the optical waveguide direction D, and the Y-axis direction is a direction parallel to the optical waveguide direction D (see FIG. 1).

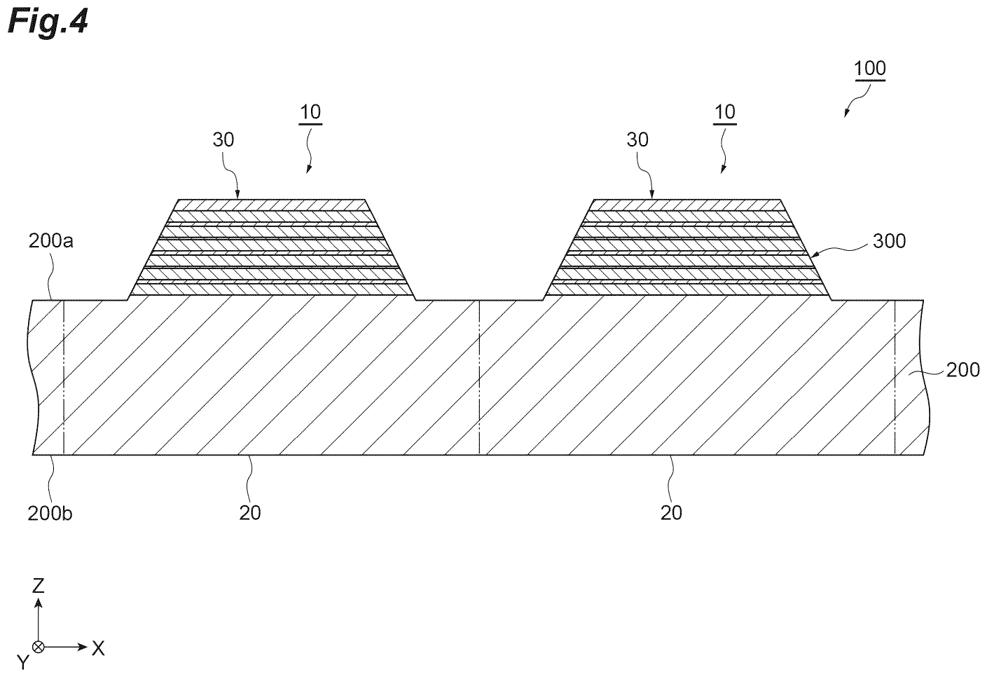

As illustrated in FIG. 4, the wafer 100 includes a substrate layer 200 and a stacked body layer 300. The substrate layer 200 has a first primary surface 200a and a second primary surface 200b opposite to the first primary surface 200a. The substrate layer 200 includes a plurality of substrate portions 20 to each become the semiconductor substrate 2. The substrate layer 200 is a GaAs single crystal layer. In the substrate layer 200, the Z-axis direction which is a thickness direction of the substrate layer 200 is a [100] direction, the Y-axis direction is a [01-1] direction, and the X-axis direction is a [0-1-1] direction. The stacked body layer 300 is formed on the first primary surface 200a of the substrate layer 200. The stacked body layer 300 includes a plurality of stacked body portions 30 to each become the semiconductor stacked body 3. In the present embodiment, a region of the first primary surface 200a of the substrate layer 200 where the plurality of stacked body portions 30 are not formed corresponds to a part of the first primary surface 100a of the wafer 100, and the second primary surface 200b of the substrate layer 200 corresponds to the second primary surface 100b of the wafer 100.

As illustrated in FIG. 3, the plurality of device portions 10 arranged in the X-axis direction are partitioned by a plurality of first boundary lines B1 as viewed from the Z-axis direction. Each first boundary line B1 extends in the Y-axis direction. That is, a direction in which each first boundary line B1 extends is the [01-1] direction. The plurality of device portions 10 arranged in the Y-axis direction are partitioned by a plurality of second boundary lines B2 as viewed from the Z-axis direction. A plurality of cleavage lines CL are set in the wafer 100. Each cleavage line CL includes the plurality of second boundary lines B2 continuous in the X-axis direction. Each second boundary line B2 and each cleavage line CL extend in the X-axis direction. That is, a direction in which each second boundary line B2 and each cleavage line CL extend is the [0-1-1] direction. Note that, an orientation flat 100c indicating a crystal orientation of the substrate layer 200 is provided in the wafer 100.

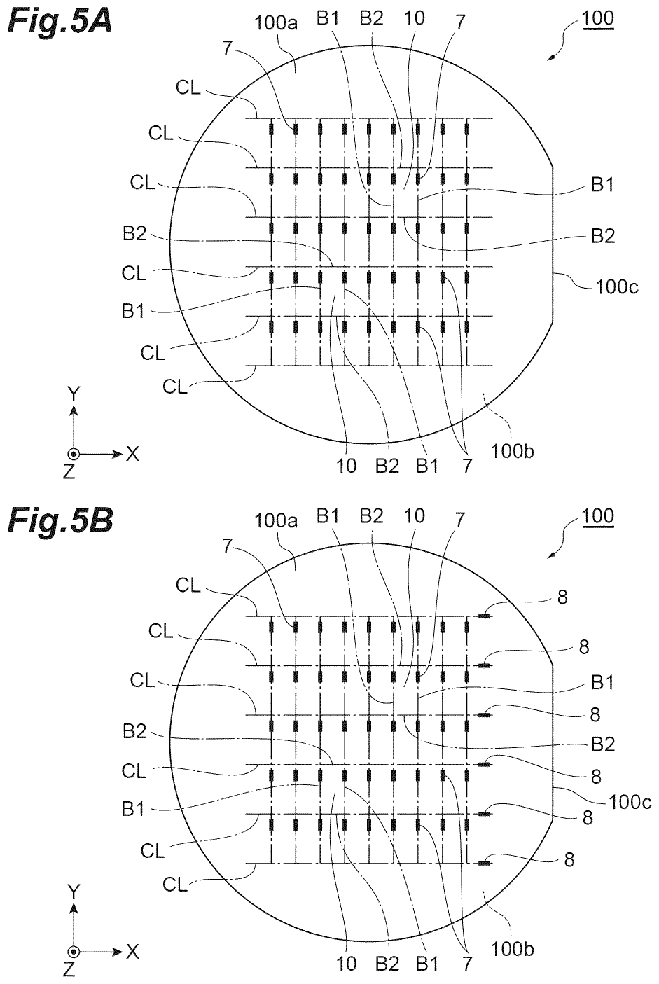

Subsequently, as illustrated in FIG. 5A, a pressing mark group 7 is formed on the first primary surface 100a of the wafer 100 to be positioned at each first boundary line B1 as viewed from the Z-axis direction (second step). That is, the pressing mark group 7 is formed for each first boundary line B1 partitioning the device portions 10 adjacent to each other in the X-axis direction. In the present embodiment, the pressing mark group 7 is formed on the first primary surface 200a of the substrate layer 200 exposed between the stacked body portions 30 adjacent to each other in the X-axis direction. Details of the pressing mark group 7 will be described later.

Subsequently, an insulating layer to become the insulating film 4 in each device portion 10 and a first electrode layer to become the first electrode 5 in each device portion 10 are formed on the first primary surface 100a of the wafer 100. As a result, the pressing mark group 7 is covered with the insulating layer. In addition, a second electrode layer to become the second electrode 6 in each device portion 10 is formed on the second primary surface 100b of the wafer 100. The substrate layer 200 may be thinned by polishing the second primary surface 200b of the substrate layer 200 before the second electrode layer is formed.

Subsequently, as illustrated in FIG. 5B, a cleavage start point 8 is formed on the first primary surface 100a of the wafer 100 to be positioned at each cleavage line CL as viewed from the Z-axis direction (third step). More specifically, the cleavage start point 8 is formed to be positioned at a portion of each cleavage line CL excluding the plurality of second boundary lines B2 (that is, on an extension line of the plurality of second boundary lines B2 continuous in the X-axis direction). In the present embodiment, the pressing mark group 7 and the cleavage start point 8 are formed on the first primary surface 100a which is the same primary surface. Note that, the cleavage start point 8 is formed by a known point scribe using a diamond tool or the like.

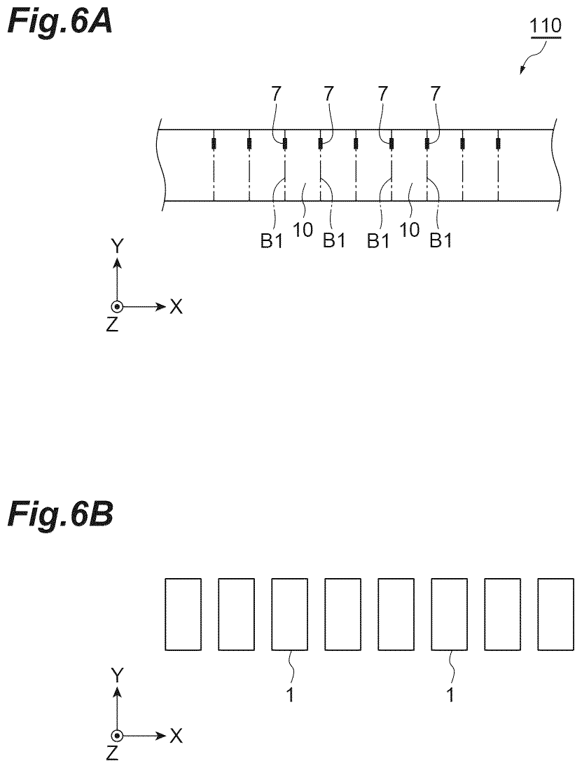

Subsequently, the wafer 100 is cleaved along each cleavage line CL with the cleavage start point 8 as a start point, and a plurality of laser bars 110 are obtained as illustrated in FIG. 6A (fourth step). The laser bar 110 includes the plurality of device portions 10 arranged in a line in the X-axis direction. Note that, when the wafer 100 is cleaved along each cleavage line CL, the insulating layer and the second electrode layer described above are simultaneously cut. Subsequently, a low reflection film or a high reflection film is formed on one end surface of the laser bar 110 perpendicular to the Y-axis direction. The one end surface is a surface including one end surface 3a or the other end surface 3a of each device portion 10. Subsequently, the laser bar 110 is cleaved along each first boundary line B1 with the pressing mark group 7 as a start point, and a plurality of semiconductor laser devices 1 are obtained as illustrated in FIG. 6B (fifth step). Note that, when the laser bar 110 is cleaved along each first boundary line B1, the insulating layer, the second electrode layer, and the reflection film (low reflection film or high reflection film) described above are simultaneously cut.

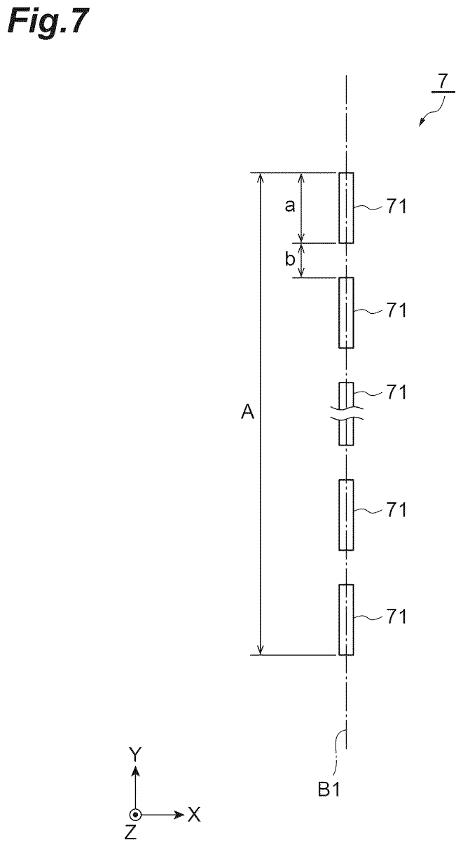

Here, the pressing mark group 7 will be described in detail. As illustrated in FIG. 7, the pressing mark group 7 includes a plurality of continuous pressing marks 71. The plurality of continuous pressing mark 71 are separated from each other, and are arranged in a line on the first boundary line B1 as viewed from the Z-axis direction.

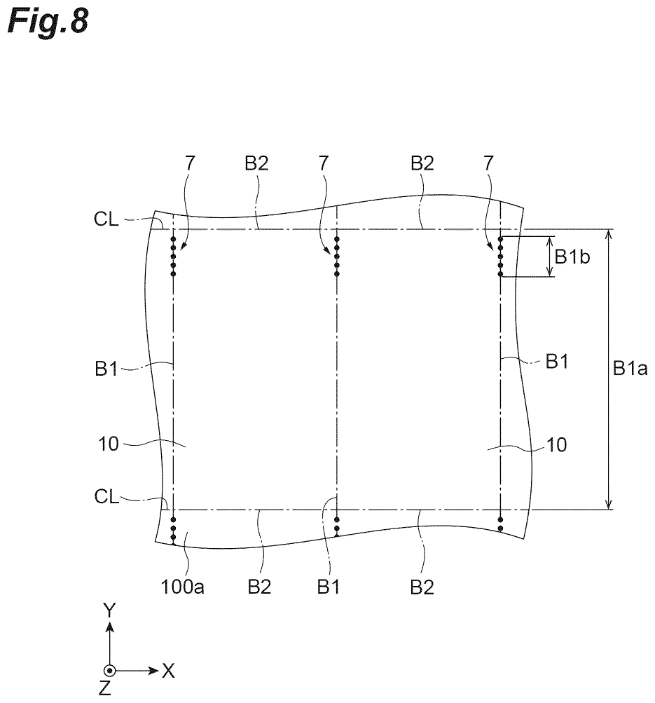

The “plurality of continuous pressing marks 71” are defined as follows. That is, when a length of each pressing mark 71 in a direction parallel to the first boundary line B1 is a and an interval between the pressing marks 71 adjacent to each other in the direction parallel to the first boundary line B1 is b, a plurality of pressing marks 71 formed to satisfy “a:b=1:X”, “0.1<X<10”, and “a<100 μm” are the “plurality of continuous pressing marks 71”. Alternatively, the “plurality of continuous pressing mark 71” are defined as follows. That is, when the number of pressing marks 71 is n, a length of the first boundary line B1 is B1a (see FIG. 8) and a length of the pressing mark group 7 in the direction parallel to the first boundary line B1 is A, a plurality of pressing marks 71 formed to satisfy “n≥3”, “A<B1a/2”, and “a<100 μm” are the “plurality of continuous pressing marks 71”. As an example, the length of the first boundary line B1 is about 700 μm, and the length of the pressing mark group 7 in the direction parallel to the first boundary line B1 is about 100 μm. As an example, the length of the pressing mark 71 in the direction parallel to the first boundary line B1 is about 10 μm, and the interval between the pressing marks 71 adjacent to each other in the direction parallel to the first boundary line B1 is about 2 μm. In addition, the length a and/or the interval b of the pressing mark 71 may not be completely uniform due to a difference in a contact angle of a tool for forming the pressing mark 71 with respect to the wafer. For example, the lengths a of the pressing marks 71 at both ends of the “plurality of continuous pressing marks 71” may be shorter than the other pressing marks 71. Even in a case where the length a and/or the interval b of the pressing mark 71 are not completely uniform as described above, an average value of the lengths a and an average value of the intervals b of the pressing marks 71 among the “plurality of continuous pressing marks 71” may satisfy the above definition.

As illustrated in FIG. 8, the pressing mark group 7 is formed along each first boundary line B1 not to be positioned at each cleavage line CL (that is, the pressing mark group 7 does not cross each cleavage line CL). A length B1b of a portion where the pressing mark group 7 is formed at each first boundary line B1 is less than or equal to ½ of a length B1a of each first boundary line B1. More preferably, the length B1b of the portion where the pressing mark group 7 is formed at each first boundary line B1 is less than or equal to 1/7 of the length B1a of each first boundary line B1. In the example illustrated in FIG. 8, one pressing mark group 7 is formed along one first boundary line B1, and the one pressing mark group 7 is formed along one end of the one first boundary line B1. However, a plurality of pressing mark groups 7 may be formed along one first boundary line B1. In this case, the length B1b of the portion where the pressing mark group 7 is formed at each first boundary line B1 is the sum of the lengths of the plurality of pressing mark groups 7 formed along one first boundary line B1.

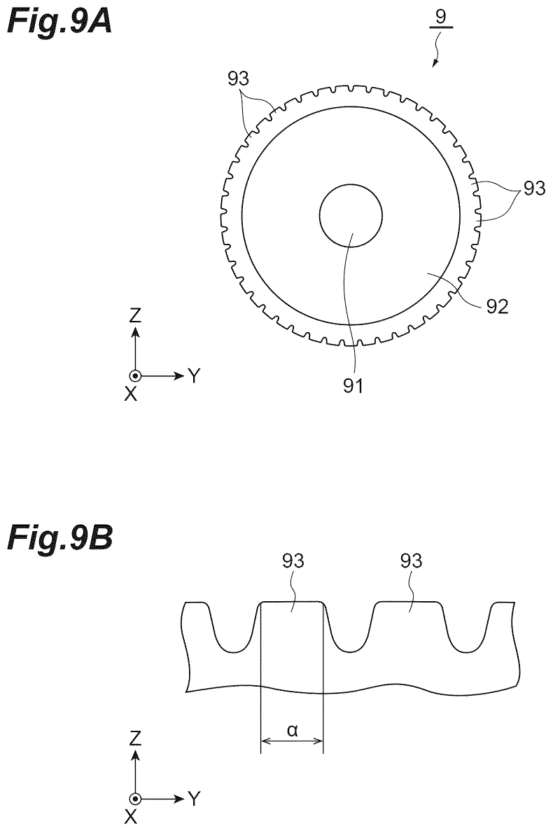

In the present embodiment, the pressing mark group 7 is formed by a gear-shaped wheel 9 as illustrated in FIG. 9A. The wheel 9 includes a shaft portion 91, a body portion 92, and a plurality of teeth 93. The body portion 92 is formed in a disk shape. The shaft portion 91 is fixed to the body portion 92 in a state of penetrating a central portion of the body portion 92. The plurality of teeth 93 are arranged at a constant pitch along an outer edge of the body portion 92. The body portion 92 and the plurality of teeth 93 are integrally rotated by the rotation of the shaft portion 91, and thus, the wheel 9 is rolled on a front surface of an object. In the present embodiment, the wheel 9 is rolled on the first primary surface 100a of the wafer 100 along each first boundary line B1, and thus, the pressing mark group 7 is formed.

When a length of each tooth 93 in a circumferential direction is a as illustrated in FIG. 9B and a length of each pressing mark 71 in a direction parallel to the first boundary line B1 is a as illustrated in FIG. 7, the pressing mark group 7 is formed such that the length a of each pressing mark 71 corresponds to the length a of each tooth 93. The “length a of each pressing mark 71 corresponds to the length a of each tooth 93” means that “α≤a≤1.5α” is satisfied. When the gear-shaped wheel 9 is used to form the pressing mark group 7, the pressing mark group 7 is formed such that the length a of each pressing mark 71 is less than or equal to twice the length a of each tooth 93. In addition, as described above, due to the difference in the contact angle of the tool for forming the pressing mark 71 with respect to the wafer, the length a of the pressing mark 71 at both ends of the “plurality of continuous pressing marks 71” may be shorter than lengths of the other pressing marks 71. Even in such a case, an average value of the lengths a of the pressing marks 71 in the “plurality of continuous pressing marks 71” may satisfy the above definition with respect to the length a of each tooth 93.

### Actions and Effects

In the method for manufacturing the semiconductor laser device 1, the pressing mark group 7 is formed on the first primary surface 100a of the wafer 100 to be positioned at each of the plurality of first boundary lines B1 that partition the plurality of device portions 10 arranged in the X-axis direction perpendicular to the optical waveguide direction D of the semiconductor stacked body 3. As a result, it is possible to suppress occurrence of a lateral crack along each first boundary line B1. In addition, for example, as compared with a case where the laser bar is scribed along each first boundary line B1 by a diamond tool, large-scale brittle fracture due to the lateral crack is less likely to occur, and it is possible to suppress occurrence of debris. Thus, according to the method for manufacturing the semiconductor laser device 1, it is possible to suppress remaining of the lateral crack in the obtained semiconductor laser device 1.

In the method for manufacturing the semiconductor laser device 1, in the wafer 100 including the plurality of device portions 10 arranged in a matrix in the X-axis direction perpendicular to the optical waveguide direction D and the Y-axis direction parallel to the optical waveguide direction D, the cleavage start point 8 is formed on the first primary surface 100a of the wafer 100 to be positioned at each of the plurality of cleavage lines CL including the plurality of second boundary lines B2 that partition the plurality of device portions 10 arranged in the Y-axis direction. Then, after the formation of the pressing mark group 7 and the formation of the cleavage start point 8 are performed, the wafer 100 is cleaved along each cleavage line CL, and the laser bar 110 is further cleaved along each first boundary line B1. As a result, since the pressing mark group 7 is formed in the state of the wafer 100 including the plurality of device portions 10 arranged in a matrix, time required to obtain the plurality of semiconductor laser devices 1 can be shortened as compared with a case where the pressing mark group 7 is formed on each of the plurality of laser bars 110 including the plurality of device portions arranged in a line.

In the method for manufacturing the semiconductor laser device 1, the cleavage start point 8 is formed after the formation of the pressing mark group 7. As a result, the plurality of pressing mark groups 7 can be formed in a state where the wafer 100 along the cleavage line CL is prevented from being cleaved.

In the method for manufacturing the semiconductor laser device 1, the pressing mark group 7 and the cleavage start point 8 are formed on the first primary surface 100a which is the same primary surface. As a result, for example, in a case where cleaving is performed in two orthogonal directions (for example, the X-axis direction and the Y-axis direction), since a difference in cleavability in each direction can be used, rigidity of the wafer 100 can be kept high. Specifically, the formation of the pressing mark and the cleavage start point is as follows. In a case where the first primary surface 100a which is a (100) plane is a machined surface, due to physical properties of the crystal, the [01-1] direction (in the present embodiment, the Y-axis direction) is a direction in which an initial crack necessary for cleavage (a crack directed from the machined surface to a facing surface) is less likely to be formed, and the [0-1-1] direction (in the present embodiment, the X-axis direction) is a direction in which an initial crack necessary for cleavage is likely to be formed. In a case where the second primary surface 100b which is a (−100) plane is a machined surface, a relationship therebetween is reversed. In either case, the cleaving is more likely to be performed as the initial crack is formed deeper. In the method for manufacturing the semiconductor laser device 1, the rigidity of the wafer 100 in a state where the pressing mark group 7 and the cleavage start point 8 are formed can be kept high by forming the pressing mark group 7 on the first primary surface 100a along the [01-1] direction and forming the cleavage start point 8 on the first primary surface 100a along the [0-1-1] direction. In addition, the rigidity of the laser bar 110 (that is, the laser bar 110 in a state where the pressing mark group 7 is formed) obtained by cleaving the wafer 100 along the cleavage start point 8 can also be kept high. Note that, in a case where the pressing mark group 7 and the cleavage start point 8 are formed on the second primary surface 100b, similar effects can be obtained by forming the pressing mark group 7 on the second primary surface 100b along the [0-1-1] direction and forming the cleavage start point 8 on the second primary surface 100b along the [01-1] direction.

In the method for manufacturing the semiconductor laser device 1, the cleavage start point 8 is formed to be positioned at a portion of each cleavage line CL excluding the plurality of second boundary lines B2. As a result, since an influence of the cleavage start point 8 is less likely to be exerted on the plurality of device portions 10, it is possible to obtain the semiconductor laser device 1 in which the pair of end surfaces 3a perpendicular to the optical waveguide direction D is accurately formed.

In the method for manufacturing the semiconductor laser device 1, the pressing mark group 7 is formed not to be positioned at each cleavage line CL. As a result, since an influence of the pressing mark group 7 is less likely to be exerted on the cleavage of the wafer 100 along the cleavage line CL, it is possible to obtain the semiconductor laser device 1 in which the pair of end surfaces 3a perpendicular to the optical waveguide direction D is accurately formed.

In the method for manufacturing the semiconductor laser device 1, the length B1b of the portion where the pressing mark group 7 is formed at each first boundary line B1 is less than or equal to ½ of the length B1a of each first boundary line B1. As a result, since the influence of the pressing mark group 7 on the semiconductor laser device 1 is suppressed, a yield of the semiconductor laser device 1 can be improved.

In the method for manufacturing the semiconductor laser device 1, the length B1b of the portion where the pressing mark group 7 is formed at each first boundary line B1 is less than or equal to 1/7 of the length B1a of each first boundary line B1. As a result, since the influence of the pressing mark group 7 on the semiconductor laser device 1 is more reliably suppressed, the yield of the semiconductor laser device 1 can be further improved.

In the method for manufacturing the semiconductor laser device 1, the gear-shaped wheel 9 is rolled on the first primary surface 100a of the wafer 100 along each first boundary line B1, and thus, the pressing mark group 7 is formed. As a result, the pressing mark group 7 can be efficiently and accurately formed.

In the method for manufacturing the semiconductor laser device 1, in the wafer 100, the thickness direction of the substrate layer 200 is the [100] direction, and the direction in which each first boundary line B1 extends is the [01-1] direction. Mechanical strength of the wafer 100 on which the pressing mark group 7 is formed along each first boundary line B1 is maintained more in a case where the direction in which each first boundary line B1 extends is the [01-1] direction than in a case where the direction in which each first boundary line B1 extends is the [0-1-1] direction. Thus, it is possible to suppress the wafer 100 from being damaged when further processing (for example, the formation of the insulating layer, the formation of the first electrode layer, the polishing of the second primary surface 200b of the substrate layer 200, the formation of the second electrode layer, and the like.) is performed on the wafer 100 on which the pressing mark group 7 is formed.

In the method for manufacturing the semiconductor laser device 1, the substrate layer 200 of the wafer 100 is a GaAs single crystal layer. As described above, even in a case where the substrate layer 200 of the wafer 100 is a GaAs single crystal layer in which the lateral crack is likely to occur, it is possible to effectively suppress the remaining of the lateral crack in the obtained semiconductor laser device 1.

In the method for manufacturing the semiconductor laser device 1, the pressing mark group 7 is formed such that the length a of the pressing mark 71 of each of the plurality of continuous pressing marks 71 is less than or equal to twice the length a of the tooth 93 of the wheel 9 for forming the pressing mark group 7. As a result, it is possible to suppress the occurrence of the lateral crack caused by dragging of the teeth 93 of the wheel 9.

In the method for manufacturing the semiconductor laser device 1, the pressing mark group 7 is formed such that the length a of the pressing marks 71 of each of the plurality of continuous pressing marks 71 corresponds to the length a of the tooth 93 of the wheel 9 for forming the pressing mark group 7. As a result, it is possible to more reliably suppress the occurrence of the lateral crack caused by dragging of the teeth 93 of the wheel 9.

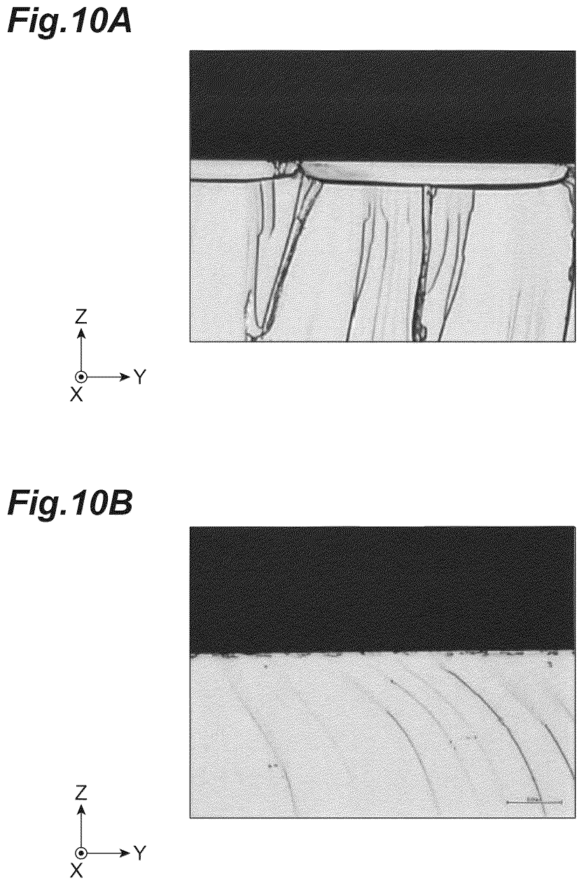

FIG. 10A is a diagram showing a photograph of a part of a side surface of a semiconductor laser device obtained by the method for manufacturing a semiconductor laser device according to a comparative example, and FIG. 10B is a diagram showing a photograph of a part of a side surface of a semiconductor laser device obtained by a method for manufacturing a semiconductor laser device according to an example. In the method for manufacturing a semiconductor laser device according to the comparative example, a plurality of semiconductor laser devices were obtained by scribing a laser bar along a first boundary line with a diamond tool and cleaving the laser bar along the first boundary line. In the semiconductor laser device obtained by the method for manufacturing a semiconductor laser device according to the comparative example, as illustrated in FIG. 10A, a lateral crack (black streak extending horizontally in FIG. 10A) were generated on the side surface of the semiconductor laser device along the first boundary line. In contrast, in the method for manufacturing a semiconductor laser device according to the example, a plurality of semiconductor laser devices were obtained by forming a pressing mark group on a laser bar along a first boundary line and cleaving the laser bar along the first boundary line. In the semiconductor laser device obtained by the method for manufacturing a semiconductor laser device according to the example, as illustrated in FIG. 10B, a lateral crack was hardly generated on the side surface of the semiconductor laser device along the first boundary line. In addition, in the method for manufacturing a semiconductor laser device according to the example, the occurrence of debris was also suppressed as compared with the method for manufacturing a semiconductor laser device according to the comparative example.

### [Modification]

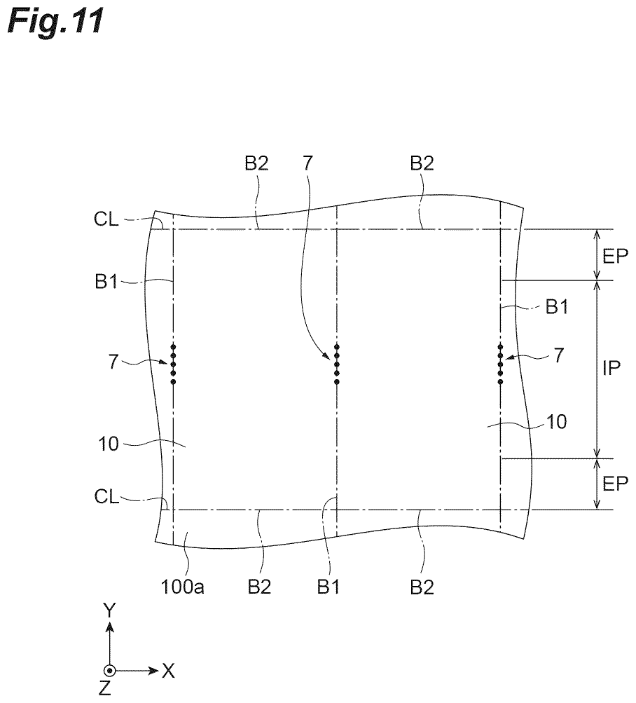

The present disclosure is not limited to the above embodiment. For example, the position and the number of pressing mark groups 7 formed for one first boundary line B1 are not particularly limited. As an example, as illustrated in FIG. 11, the pressing mark group 7 may be formed along a part of an intermediate portion IP of each first boundary line B1. In this case, the wheel 9 may be separated from the first primary surface 100a at both end portions EP of each first boundary line B1, and the wheel 9 may be rolled on the first primary surface 100a along the intermediate portion IP of each first boundary line B1. When the pressing mark group 7 is formed on the intermediate portion IP of each first boundary line B1, since the influence of the pressing mark group 7 is less likely to be exerted on the cleavage of the wafer 100 along the cleavage line CL, it is possible to obtain the semiconductor laser device 1 in which the pair of end surfaces 3a perpendicular to the optical waveguide direction D is accurately formed.

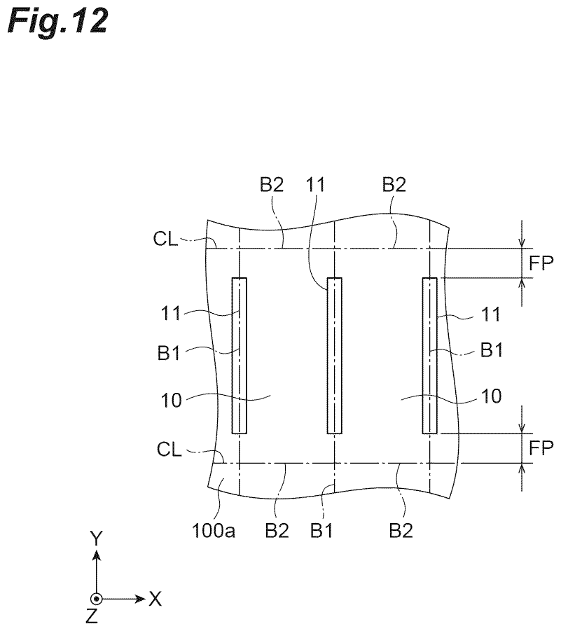

In addition, after the preparation of the wafer 100 and before the formation of the pressing mark group 7, as illustrated in FIG. 12, a mask 11 may be formed on the first primary surface 100a along a portion of each first boundary line B1 excluding a portion FP where the pressing mark group 7 is formed (sixth step). In this case, the wheel 9 may be rolled on the first primary surface 100a along the entire first boundary line B1. The mask 11 is used in this manner, and thus, it is not necessary to separate the gear-shaped wheel 9 from the wafer 100 in the portion excluding the portion FP where the pressing mark group 7 is formed. As a result, the pressing mark group 7 can be more efficiently formed.

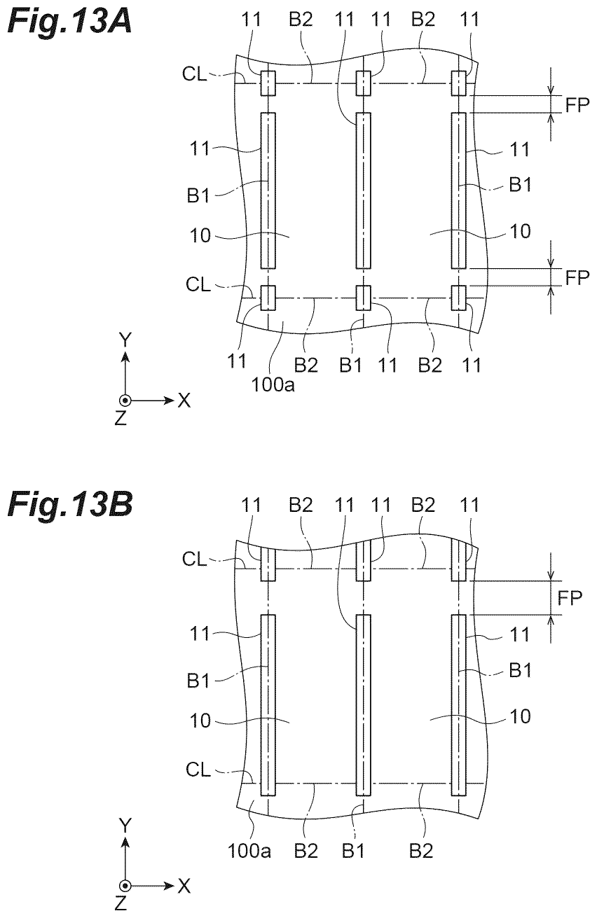

The example illustrated in FIG. 12 is an example in which both end portions of each first boundary line B1 are not covered by the mask 11 including an intersection between each first boundary line B1 and each cleavage line CL. In the example illustrated in FIG. 12, when the pressing mark 71 is not formed on the intersection between each first boundary line B1 and each cleavage line CL, since the influence of the pressing mark group 7 is less likely to be exerted on the cleavage of the wafer 100 along the cleavage line CL, it is possible to obtain the semiconductor laser device 1 in which the pair of end surfaces 3a perpendicular to the optical waveguide direction D is accurately formed. The example illustrated in FIG. 13A is an example in which both end portions of each first boundary line B1 are not covered with the mask 11 and the intermediate portion of each first boundary line B1 and the intersection between each first boundary line B1 and each cleavage line CL are covered with the mask 11. The example illustrated in FIG. 13B is an example in which one end of each first boundary line B1 is not covered with the mask 11, the other end of each first boundary line B1, the intermediate portion of each first boundary line B1, and the intersection between each first boundary line B1 and each cleavage line CL are covered with the continuous mask 11. According to the example illustrated in FIGS. 13A and 13B, it is possible to reliably prevent the pressing mark 71 from being formed on the intersection between each first boundary line B1 and each cleavage line CL.

Note that, the mask 11 is preferably removed before the wafer 100 is cleaved along each cleavage line CL. The mask 11 may be removed before the laser bar 110 is cleaved along each first boundary line B1. Alternatively, the mask 11 may not be removed in a case where the mask is thinned to such an extent that the mask does not substantially influence on cleavage. The mask 11 is, for example, a metal film, an insulating film (SiN film, SiO₂ film, or the like), or a resist film.

In addition, the semiconductor laser device 1 may have another configuration as long as the semiconductor laser device is obtained by cleavage along the first boundary line B1. As an example, the semiconductor substrate 2 may be a semiconductor substrate other than the GaAs single crystal substrate. In this case, the substrate layer 200 of the wafer 100 may also be a semiconductor layer other than the GaAs single crystal layer. In addition, the semiconductor substrate 2 may be a semiconductor substrate having an orientation other than the above-described orientation. In this case, the substrate layer 200 of the wafer 100 may also be a semiconductor layer having an orientation other than the above-described orientation. In addition, the semiconductor stacked body 3 may include at least one active layer.

In addition, a wafer including a plurality of device portions 10 arranged in a line in the X-axis direction perpendicular to the optical waveguide direction D of the semiconductor stacked body 3 (wafer corresponding to the laser bar 110) may be used as the wafer 100. In that case, the formation of the cleavage start point 8 and the cleavage of the wafer 100 along the cleavage line CL may be omitted. In addition, the pressing mark group 7 may be formed on the second primary surface 100b of the wafer 100. In addition, the cleavage start point 8 may be formed on the second primary surface 100b of the wafer 100. In addition, the pressing mark group 7 may be formed on one of the first primary surface 100a and the second primary surface 100b of the wafer 100, and the cleavage start point 8 may be formed on the other of the first primary surface 100a and the second primary surface 100b of the wafer 100. In addition, the direction in which each first boundary line B1 extends may be the [0-1-1] direction, and the direction in which each second boundary line B2 and each cleavage line CL extend may be the [01-1] direction.

In addition, in the above-described embodiment, although the formation of the pressing mark group 7 on the first primary surface 100a of the wafer 100 is performed before the formation of the insulating layer to become the insulating film 4 and the formation of the first electrode layer to become the first electrode 5, the formation of the pressing mark group 7 on the first primary surface 100a of the wafer 100 may be performed after the formation of the insulating layer and the formation of the first electrode layer, or may be performed after the formation of the insulating layer and before the formation of the first electrode layer. In these cases, before the formation of the pressing mark group 7, the insulating layer may be removed at a location where the pressing mark group 7 is formed. In addition, in the above-described embodiment, although the formation of the pressing mark group 7 on the first primary surface 100a of the wafer 100 is performed before the thinning of the substrate layer 200 and the formation of the second electrode layer to become the second electrode 6, the formation of the pressing mark group 7 on the first primary surface 100a of the wafer 100 may be performed after the thinning of the substrate layer 200 and the formation of the second electrode layer, or may be performed after the thinning of the substrate layer 200 and before the formation of the second electrode layer.

In addition, the cleavage start point 8 may be formed before the formation of the pressing mark group 7. In addition, the length B1b of the portion where the pressing mark group 7 is formed at each first boundary line B1 may exceed ½ of the length B1a of each first boundary line B1. In addition, the pressing mark group 7 may be formed by a tool other than the gear-shaped wheel 9.

The method for manufacturing a semiconductor laser device according to the present disclosure may be applied to a method for manufacturing a super luminescent diode (SLD). That is, a process similar to the process of the present disclosure may be performed on a wafer used for manufacturing the SLD. As a result, effects similar to the method for manufacturing a semiconductor laser device according to the present disclosure are obtained. That is, it is possible to suppress the remaining of the lateral crack in the obtained SLD.

A method for manufacturing a semiconductor laser device according to an aspect of the present disclosure is [1] “a method for manufacturing a semiconductor laser device that includes a semiconductor substrate, and a semiconductor stacked body including an active layer and formed on the semiconductor substrate, and the method includes a first step of preparing a wafer including a plurality of device portions to each become the semiconductor laser device, the plurality of device portions being arranged in a first direction perpendicular to an optical waveguide direction of the semiconductor stacked body, and a second step of forming a pressing mark group including a plurality of continuous pressing marks on a first primary surface of the wafer or a second primary surface opposite to the first primary surface to be positioned on each of a plurality of first boundary lines that partition the plurality of device portions arranged in the first direction after the first step”.

In the method for manufacturing a semiconductor laser device according to the above [1], the pressing mark group is formed on the first primary surface of the wafer or the second primary surface opposite to the first primary surface to be positioned at each of the plurality of first boundary lines that partition the plurality of device portions arranged in the first direction perpendicular to the optical waveguide direction of the semiconductor stacked body. As a result, it is possible to suppress the occurrence of the lateral crack along each of the plurality of first boundary lines. Thus, according to the method for manufacturing a semiconductor laser device according to the above [1], it is possible to suppress the remaining of the lateral crack in the obtained semiconductor laser device.

The method for manufacturing a semiconductor laser device according to the aspect of the present disclosure may be [2] “the method for manufacturing a semiconductor laser device according to the above [1] further includes a third step of forming a cleavage start point on the first primary surface or the second primary surface to be positioned on each of a plurality of cleavage lines including a plurality of second boundary lines that partition the plurality of device portions arranged in a second direction on the wafer including the plurality of device portions arranged in a matrix in the first direction and the second direction parallel to the optical waveguide direction after the first step, a fourth step of cleaving the wafer along each of the plurality of cleavage lines and obtaining a plurality of laser bars each including the plurality of device portions arranged in the first direction after the second step and the third step, and a fifth step of cleaving each of the plurality of laser bars along each of the plurality of first boundary lines after the fourth step”. According to the method for manufacturing a semiconductor laser device according to the above [2], since the pressing mark group is formed in a state of the wafer including the plurality of device portions arranged in the matrix, the time required to obtain the plurality of semiconductor laser devices can be shortened as compared with a case where the pressing mark group is formed on each of the plurality of laser bars including the plurality of device portions arranged in a line.

The method for manufacturing a semiconductor laser device according to the aspect of the present disclosure may be [3] “in the method for manufacturing a semiconductor laser device according to the above [2], the third step is performed after the second step”. According to the method for manufacturing a semiconductor laser device according to the above [3], in the state of the wafer including the plurality of device portions arranged in the matrix, the pressing mark group is formed before the cleavage start point is formed, and thus, it is possible to form the plurality of pressing mark groups in a state where the wafer is prevented from being cleaved along the cleavage line.

The method for manufacturing a semiconductor laser device according to the aspect of the present disclosure may be [4] “in the method for manufacturing a semiconductor laser device according to the above [2] or [3], the pressing mark group and the cleavage start point are formed on the same primary surface of the first primary surface and the second primary surface”. According to the method for manufacturing a semiconductor laser device according to the above [4], for example, in a case where cleaving is performed in two orthogonal directions, since a difference in cleavability in each direction can be used, the rigidity of the wafer can be kept high.

The method for manufacturing a semiconductor laser device according to the aspect of the present disclosure may be [5] “in the method for manufacturing a semiconductor laser device according to any one of the above [2] to [4], in the third step, the cleavage start point is formed to be positioned at a portion of each of the plurality of cleavage lines excluding the plurality of second boundary lines”. According to the method for manufacturing a semiconductor laser device according to the above [5], since the influence of the cleavage start point is less likely to be exerted on the plurality of device portions, it is possible to obtain the semiconductor laser device in which the pair of end surfaces perpendicular to the optical waveguide direction is accurately formed.

The method for manufacturing a semiconductor laser device according to the aspect of the present disclosure may be [6] “in the method for manufacturing a semiconductor laser device according to any one of the above [2] to [5], in the second step, the pressing mark group is formed such that the pressing mark group is not to be positioned on each of the plurality of cleavage lines”. According to the method for manufacturing a semiconductor laser device according to the above [6], since the influence of the pressing mark group is less likely to be exerted on the cleavage of the wafer along the cleavage line, it is possible to obtain the semiconductor laser device in which the pair of end surfaces perpendicular to the optical waveguide direction is accurately formed.

The method for manufacturing a semiconductor laser device according to the aspect of the present disclosure may be [7] “in the method for manufacturing a semiconductor laser device according to any one of the above [1] to [6], a length of a portion where the pressing mark group is formed in each of the plurality of first boundary lines is less than or equal to ½ of a length of each of the plurality of first boundary lines”. According to the method for manufacturing a semiconductor laser device according to the above [7], since the influence on the semiconductor laser device due to the pressing mark group is suppressed, the yield of the semiconductor laser device can be improved.

The method for manufacturing a semiconductor laser device according to the aspect of the present disclosure may be [8] “in the method for manufacturing a semiconductor laser device according to the above [7], a length of a portion where the pressing mark group is formed in each of the plurality of first boundary lines is less than or equal to 1/7 of a length of each of the plurality of first boundary lines”. According to the method for manufacturing a semiconductor laser device according to the above [8], since the influence on the semiconductor laser device due to the pressing mark group is more reliably suppressed, the yield of the semiconductor laser device can be further improved.

The method for manufacturing a semiconductor laser device according to the aspect of the present disclosure may be [9] “in the method for manufacturing a semiconductor laser device according to any one of the above [1] to [8], in the second step, the pressing mark group is formed by rolling a gear-shaped wheel on the first primary surface or the second primary surface along each of the plurality of first boundary lines”. According to the method for manufacturing a semiconductor laser device according to the above [9], the pressing mark group can be efficiently and accurately formed.

The method for manufacturing a semiconductor laser device according to the aspect of the present disclosure may be [10] “the method for manufacturing a semiconductor laser device according to the above [9] further includes a sixth step of forming a mask on the first primary surface or the second primary surface along a portion of each of the plurality of first boundary lines excluding a portion where the pressing mark group is formed after the first step and before the second step”. According to the method of manufacturing a semiconductor laser device according to the above [10], since it is not necessary to separate the gear-shaped wheel from the wafer in the portion excluding the portion where the pressing mark group is formed, the pressing mark group can be more efficiently formed.

The method for manufacturing a semiconductor laser device according to the aspect of the present disclosure may be [11] “in the method for manufacturing a semiconductor laser device according to the above [10], in the second step, the wheel is rolled on the first primary surface or the second primary surface along the entire of each of the plurality of first boundary lines”. According to the method of manufacturing a semiconductor laser device according to the above [11], the pressing mark group can be more efficiently formed in the portion excluding the portion where the pressing mark group is formed as compared with a case where the gear-shaped wheel is separated from the wafer.

The method for manufacturing a semiconductor laser device according to the aspect of the present disclosure may be [12] “in the method for manufacturing a semiconductor laser device according to the above [9], in the second step, the wheel is separated from the first primary surface or the second primary surface at both end portions of each of the plurality of first boundary lines, and the wheel is rolled on the first primary surface or the second primary surface along an intermediate portion of each of the plurality of first boundary lines”. According to the method for manufacturing a semiconductor laser device according to the above [12], since the influence of the pressing mark group is less likely to affect the cleavage of the wafer along the cleavage line, it is possible to obtain the semiconductor laser device in which the pair of end surfaces perpendicular to the optical waveguide direction is accurately formed.

The method for manufacturing a semiconductor laser device according to the aspect of the present disclosure may be [13] “in the method for manufacturing a semiconductor laser device according to any one of the above [1] to [12], a thickness direction of a substrate layer including a plurality of substrate portions of the wafer to each become the semiconductor substrate is a [100] direction, and a direction in which each of the plurality of first boundary lines extends is a [01-1] direction”. The mechanical strength of the wafer on which the pressing mark group is formed along each of the plurality of first boundary lines is maintained in a case where the direction in which each of the plurality of first boundary lines extends is the [01-1] direction rather than a case where the direction in which each of the plurality of first boundary lines extends is the [0-1-1] direction. Thus, according to the method of manufacturing a semiconductor laser device according to the above [13], it is possible to suppress damage to the wafer when further processing is performed on the wafer on which the pressing mark group is formed.

The method for manufacturing a semiconductor laser device according to the aspect of the present disclosure may be [14] “in the method for manufacturing a semiconductor laser device according to any one of the above [1] to [13], a substrate layer including a plurality of substrate portions of the wafer to each become the semiconductor substrate is a GaAs single crystal layer”. According to the method of manufacturing a semiconductor laser device according to the above [14], even in a case where the substrate layer of the wafer is a GaAs single crystal layer in which the lateral crack is likely to occur, it is possible to effectively suppress the remaining of the lateral crack in the obtained semiconductor laser device.

The method for manufacturing a semiconductor laser device according to the aspect of the present disclosure may be [15] “in the method for manufacturing a semiconductor laser device according to any one of the above [1] to [14], in the second step, the pressing mark group is formed such that a length of each pressing mark of the plurality of continuous pressing marks is less than or equal to twice a length of a tooth of a tool for forming the pressing mark group”. According to the method of manufacturing a semiconductor laser device according to the above [15], it is possible to suppress the occurrence of the lateral crack due to dragging of the teeth of the tool.

The method for manufacturing a semiconductor laser device according to the aspect of the present disclosure may be [16] “in the method for manufacturing a semiconductor laser device according to the above [15], in the second step, the pressing mark group is formed such that a length of each pressing mark of the plurality of continuous pressing marks corresponds to a length of a tooth of a tool for forming the pressing mark group”. According to the method for manufacturing a semiconductor laser device according to the above [16], it is possible to more reliably suppress the occurrence of the lateral crack caused by dragging of the teeth of the tool.

According to the present disclosure, it is possible to provide the method for manufacturing a semiconductor laser device capable of suppressing the remaining of the lateral crack in the obtained semiconductor laser device.

What is claimed is:

1. A method for manufacturing a semiconductor laser device that includes a semiconductor substrate, and a semiconductor stacked body including an active layer and formed on the semiconductor substrate, the method comprising:
a first step of preparing a wafer including a plurality of device portions to each become the semiconductor laser device, the plurality of device portions being arranged in a first direction perpendicular to an optical waveguide direction of the semiconductor stacked body; and
a second step of forming a pressing mark group including a plurality of continuous pressing marks on a first primary surface of the wafer or a second primary surface opposite to the first primary surface to be positioned on each of a plurality of first boundary lines that partition the plurality of device portions arranged in the first direction after the first step.

2. The method for manufacturing a semiconductor laser device according to claim 1, further comprising:
a third step of forming a cleavage start point on the first primary surface or the second primary surface to be positioned on each of a plurality of cleavage lines including a plurality of second boundary lines that partition the plurality of device portions arranged in a second direction on the wafer including the plurality of device portions arranged in a matrix in the first direction and the second direction parallel to the optical waveguide direction after the first step;
a fourth step of cleaving the wafer along each of the plurality of cleavage lines and obtaining a plurality of laser bars each including the plurality of device portions arranged in the first direction after the second step and the third step; and
a fifth step of cleaving each of the plurality of laser bars along each of the plurality of first boundary lines after the fourth step.

3. The method for manufacturing a semiconductor laser device according to claim 2, wherein the third step is performed after the second step.

4. The method for manufacturing a semiconductor laser device according to claim 2, wherein the pressing mark group and the cleavage start point are formed on the same primary surface of the first primary surface and the second primary surface.

5. The method for manufacturing a semiconductor laser device according to claim 2, wherein in the third step, the cleavage start point is formed to be positioned at a portion of each of the plurality of cleavage lines excluding the plurality of second boundary lines.

6. The method for manufacturing a semiconductor laser device according to claim 2, wherein in the second step, the pressing mark group is formed such that the pressing mark group is not to be positioned on each of the plurality of cleavage lines.

7. The method for manufacturing a semiconductor laser device according to claim 1, wherein a length of a portion where the pressing mark group is formed in each of the plurality of first boundary lines is less than or equal to ½ of a length of each of the plurality of first boundary lines.

8. The method for manufacturing a semiconductor laser device according to claim 7, wherein a length of a portion where the pressing mark group is formed in each of the plurality of first boundary lines is less than or equal to 1/7 of a length of each of the plurality of first boundary lines.

9. The method for manufacturing a semiconductor laser device according to claim 1, wherein in the second step, the pressing mark group is formed by rolling a gear-shaped wheel on the first primary surface or the second primary surface along each of the plurality of first boundary lines.

10. The method for manufacturing a semiconductor laser device according to claim 9, further comprising: a sixth step of forming a mask on the first primary surface or the second primary surface along a portion of each of the plurality of first boundary lines excluding a portion where the pressing mark group is formed after the first step and before the second step.

11. The method for manufacturing a semiconductor laser device according to claim 10, wherein in the second step, the wheel is rolled on the first primary surface or the second primary surface along the entire of each of the plurality of first boundary lines.

12. The method for manufacturing a semiconductor laser device according to claim 9, wherein in the second step, the wheel is separated from the first primary surface or the second primary surface at both end portions of each of the plurality of first boundary lines, and the wheel is rolled on the first primary surface or the second primary surface along an intermediate portion of each of the plurality of first boundary lines.

13. The method for manufacturing a semiconductor laser device according to claim 1, wherein a thickness direction of a substrate layer including a plurality of substrate portions of the wafer to each become the semiconductor substrate is a [100] direction, and
a direction in which each of the plurality of first boundary lines extends is a [01-1] direction.

14. The method for manufacturing a semiconductor laser device according to claim 1, wherein a substrate layer including a plurality of substrate portions of the wafer to each become the semiconductor substrate is a GaAs single crystal layer.

15. The method for manufacturing a semiconductor laser device according to claim 1, wherein in the second step, the pressing mark group is formed such that a length of each pressing mark of the plurality of continuous pressing marks is less than or equal to twice a length of a tooth of a tool for forming the pressing mark group.

16. The method for manufacturing a semiconductor laser device according to claim 15, wherein in the second step, the pressing mark group is formed such that a length of each pressing mark of the plurality of continuous pressing marks corresponds to a length of a tooth of a tool for forming the pressing mark group.
